(19) United States
(12) Patent Application Publication
(10) Pub. No.: US 2009/0042399 A1
(43) Pub. Date: Feb. 12, 2009

(54) Method for Dry Develop of Trilayer Photoresist Patterns

(76) Inventors: Brian Ashley Smith, Rolla, MO (US); David Gerald Farber, Austin, TX (US)

Correspondence Address: TEXAS INSTRUMENTS INCORPORATED, P O BOX 655474, M/S 3999, DALLAS, TX, 75265, US

(21) Appl. No.: 11/835,806

(22) Filed: Aug. 8, 2007

(51) Int. Cl. H01L 21/461

(52) U.S. Cl. 438/735; 257/E21.483

(57) ABSTRACT

A method of forming a feature on a multi-layer semiconductor is disclosed. A pattern feature is formed in an uppermost layer of the multi-layer semiconductor. The multilayer semiconductor is etched with a SO₂ based chemistry to extend the pattern feature to a lower layer of the multi-layer semiconductor. Use of the SO₂ based chemistry for etch eliminates features roughness associated with conventional CO, SiCL₄ or CO₂-based chemistries.

### FIELD

The subject matter of the disclosure relates to methods of integrated circuit etching. More particularly, the subject matter of the disclosure relates to integrated circuit etching for extremely small features.

### BACKGROUND

To avoid defects when patterning extremely small features for integrated circuits at the 45 nm node and below, a bilayer or trilayer mask pattern is frequently used, in which the fragile photoresist pattern is transferred (dry-developed) into a more robust material before the actual device film layer is etched. In the case of trilayer patterns, increased defects have been observed in a silicon trench etch process when using conventional CO, SiCL₄ or CO₂-based chemistries, caused by incomplete etching of underlying robust resist films. This leads to so-called “cone” defects, caused by nanoscale particles and blocked etch. Contact holes defectivity caused by burrs, or spikes form as the resist breaks down during the etch. These small protrusions from the side of the hole can lead to bridging of adjacent holes, thus shorting the circuit.

In general, in the process of plasma etching patterns for semiconductor devices, the edges of features can become roughened and enlarged due to the inherent instability of the photoresist mask material. Roughness degrades device performance, and features may become larger than the circuit design allows. In the case of transistor gates, roughness leads to greater off-state current. As mentioned above, oversized, rough contact holes can lead to shorting between contacts and gates. Shorting of tight-pitch trenches and via holes in dielectric films can also result from break-down of delicate 193-nm photoresists and immersion-lithography photoresists. While feature sizes shrink with each technology node, roughness does not scale down, becoming a greater percentage of the critical dimensions in the circuit and leading to worse degradation at smaller feature sizes. At the 45 nm technology node the roughness can easily comprise more than 10% of the feature size, causing significant difficulty for advanced patterning processes. Also, the size increase caused by mask material breakdown can compromise design tolerances, leading to shorting problems.

Accordingly, the present teachings solve these and other problems of the prior art's use of conventional CO, SiCL₄ or CO₂-based chemistries for a trilayer pattern.

### SUMMARY

In accordance with the teachings, a method of forming a feature on a multi-layer semiconductor is disclosed. A pattern feature is formed in an uppermost layer of the multi-layer semiconductor. The multilayer semiconductor is etched with a SO₂ based chemistry. The pattern feature is extended to a lower layer of the multi-layer semiconductor.

In accordance with the teachings, a method of forming a feature on multi-layer semiconductor is disclosed. A multi-layer semiconductor is formed comprising an underlayer resist portion. The underlayer resist portion of the multi-layer semiconductor is etched with a SO₂-based chemistry.

Additional advantages of the embodiments will be set forth in part in the description which follows, and in part will be obvious from the description, or may be learned by practice of the teachings. The advantages will be realized and attained by means of the elements and combinations particularly pointed out in the appended claims.

It is to be understood that both the foregoing general description and the following detailed description are exemplary and explanatory only and are not restrictive of the teachings, as claimed.

The accompanying drawings, which are incorporated in and constitute a part of this specification, illustrate embodiments of the teachings and together with the description, serve to explain the principles of the teachings.

### BRIEF DESCRIPTION OF THE DRAWINGS

FIG. 1A shows an example semiconductor device shown to comprise a plurality of layers prior to etching, in accordance with the principles of the present teachings.

FIG. 1B shows an example semiconductor device after etching is performed, in accordance with the principles of the present teachings.

FIG. 1C shows a contact hole created with conventional CO, SiCL₄ or CO₂-based chemistries.

FIG. 1D shows a contact hole created with the novel SO₂-based chemistry, in accordance with the principles of the present teachings.

FIGS. 2A and 2C show examples of contact hole patterns prior to etching, in accordance with the principles of the present teachings.

FIGS. 2B and 2D show a comparison of a top-down view of a plurality of contact holes before and after etching produced with conventional CO, SiCL₄ or CO₂-based chemistries and those produced with a SO₂-based chemistry, in accordance with the principles of the present teachings.

FIG. 2E shows a graphical analysis of the 3Sigma′ by slot for the contact holes produced with conventional CO, SiCL₄ or CO₂-based chemistries and those produced with a SO₂-based chemistry, in accordance with the principles of the present teachings.

### DESCRIPTION OF THE EMBODIMENTS

Reference will now be made in detail to the present embodiments, examples of which are illustrated in the accompanying drawings. Wherever possible, the same reference numbers will be used throughout the drawings to refer to the same or like parts.

Notwithstanding that the numerical ranges and parameters setting forth the broad scope of the teachings disclosed herein are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

The use of SO₂ has been studied as a dry-develop etching gas in the past. However, the novel method disclosed herein applies SO₂ etch chemistry to trilayer trench and contact hole patterns to reduce defects and roughness.

The use of SO₂-based chemistry, e.g., SO₂/O₂/Ar chemistry, in place of the usual CO, SiCl₄ or CO₂ chemistries in the dry-develop step of a trilayer pattern etch process can preserve the lithographic dimensions of features and improve the smoothness of etched features. It is also observed to reduce small blocked-etch defects during trench etching due to its more complete removal of underlayer films without compromising the pattern integrity. For contact holes, the small spikes and burrs that usually form can be reduced and/or eliminated. This is an enabling technology for the smaller patterns at the 45 nm technology node in which immersion lithography will produce smaller features and tighter pitches than ever before. SO₂ produces a passivation film on the sidewalls of the resist as it etches, resulting in better pattern fidelity and reduced roughness. The passivation film consists of sulfur and carbon compounds that inhibit etching by atomic oxygen in the plasma.

During dry development, or etching, of trilayer patterns needed for advanced lithography of circuit patterns in semiconductor processing, including immersion lithography, small particles can block the etch process. These small particles block the etch process, leaving small pillars or cones on the surface of the underlying film or stopping layer, also called micro-masking. Other defects include roughness of the pattern caused by resist break-down that take the form of spikes or burrs that can cause shorting or bridging between nearby features.

SO₂-based chemistry disclosed herein may be used to reduce pattern roughness and silicon-etch defects during the dry-develop step, also known as the underlayer (UL) etch for trilayer patterns.

SO₂-based chemistry is an enabling chemistry for immersion lithography, in which thinner and less etch-resistant spin-on-glass (SOG) materials are needed within trilayer pattern stacks. These materials tend to transfer resist roughness into underlying films during etching.

Contact pattern data shows reduced roughness when using SO₂. The cause of the improvement is improved sidewall passivation that reduces transfer of any resist roughness through the SOG layer into the underlayer (UL).

STI data shows reduced cone defects that arise as a result of micromasking defects. Unlike alternative silicon-containing chemistries, the SO₂ process provides uniform sidewall passivation without particle generation or agglomeration.

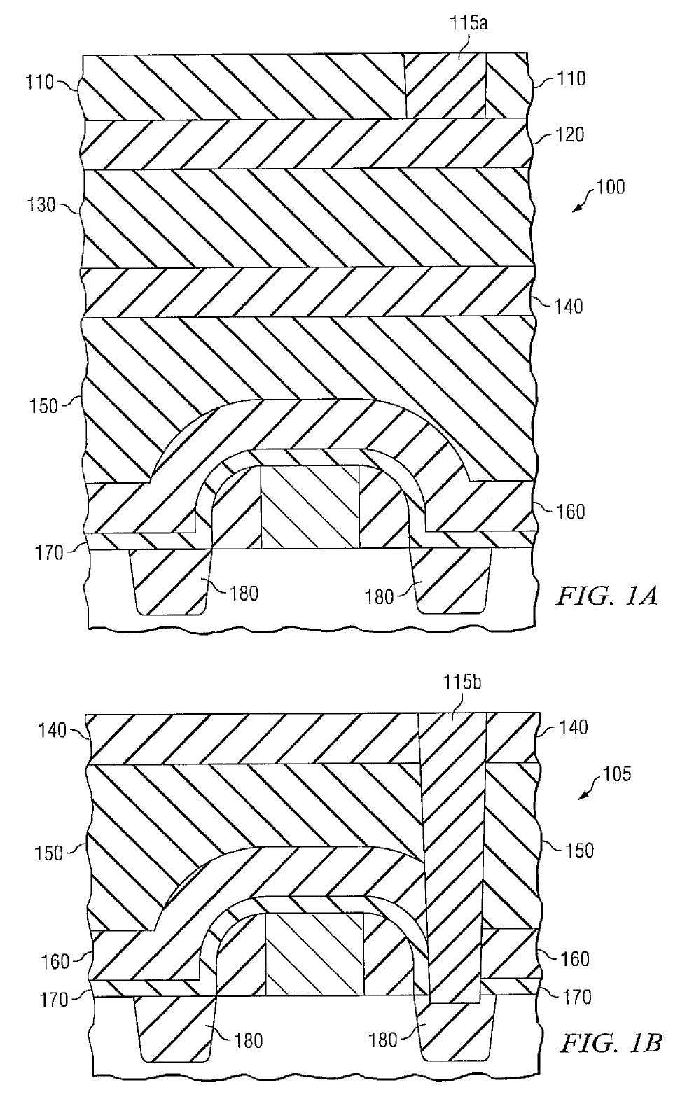

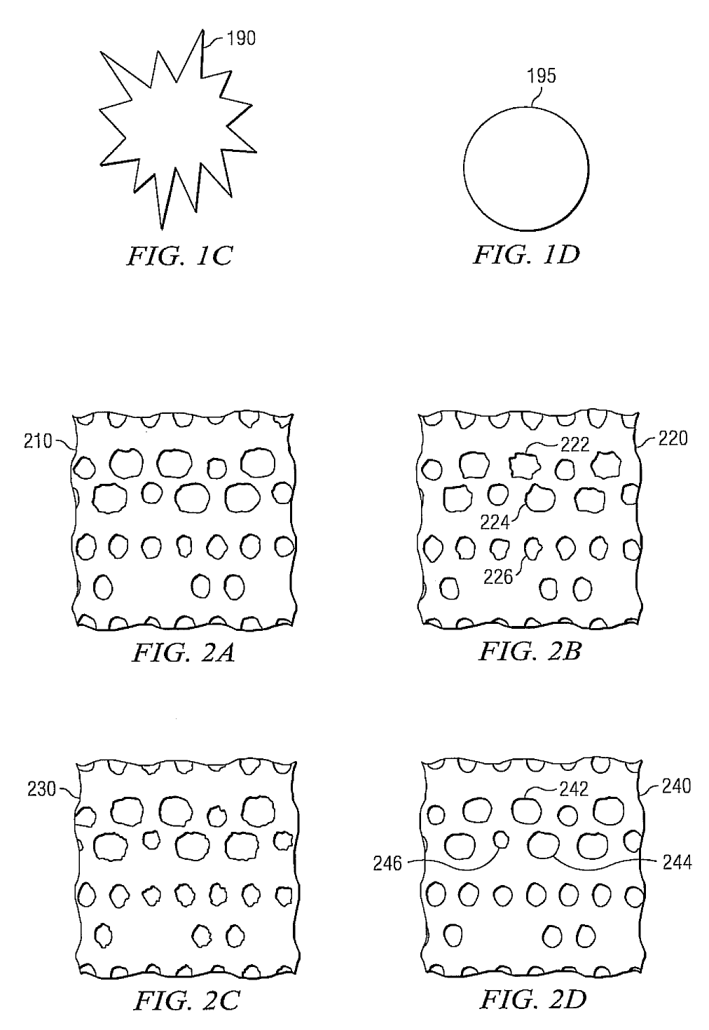

FIG. 1A shows an example semiconductor device including a plurality of layers prior to etching, in accordance with the principles of the present teachings.

The example semiconductor device 100 before etching is shown to include a plurality of layers prior to etching. In particular, the example semiconductor device 100 includes a PR layer 110, a SOG layer 120, a UL layer 130, a TEOS layer 140, a PSG layer 150, a HARP layer 160, a LINER layer 170 and a layer containing Silicide 180. A pattern feature, e.g., a contact hole 115a in the PR layer 110, is placed at a desired location to selectively mask the underlying layers from the etching chemistry. This pattern feature can be any semiconductor feature in the uppermost layer of a semiconductor structure that masks the layers beneath to create the desired final pattern structure.

FIG. 1B shows an example semiconductor device after etching is performed, in accordance with the principles of the present teachings.

In particular, the PR layer 110, the SOC layer 120 and the UL layer 130 are removed by an etching process, as shown in the example semiconductor 105. Subsequent to the etching process, the contact hole 115a becomes a full contact hole 115b through the TEOS layer 140, the PSG layer 150, the HARP layer 160 and the LINER layer 170 down to the Silicide 180.

FIG. 1C shows a contact hole created with conventional CO, SiCL₄ or CO₂-based chemistries.

Looking at the full contact hole 115b from a top-down view, conventional CO, SiCL₄ or CO₂-based chemistries produce a rough contact hole 190 having resist break-down, i.e., burrs and spikes along the perimeter of the full contact hole 115b.

FIG. 1D shows a contact hole created with the novel SO₂-based chemistry disclosed herein, in accordance with the principles of the present teachings.

In contrast to the rough contact hole 190, contact holes 115b viewed from the top-down produced using the SO₂-based chemistry, e.g., SO₂/O₂/Ar chemistry, as disclosed herein in place of conventional CO, SiCL₄ or CO₂-based chemistries produces a contact hole 195 with smooth edges, i.e., eliminates the rough contact hole 190 having resist break-down.

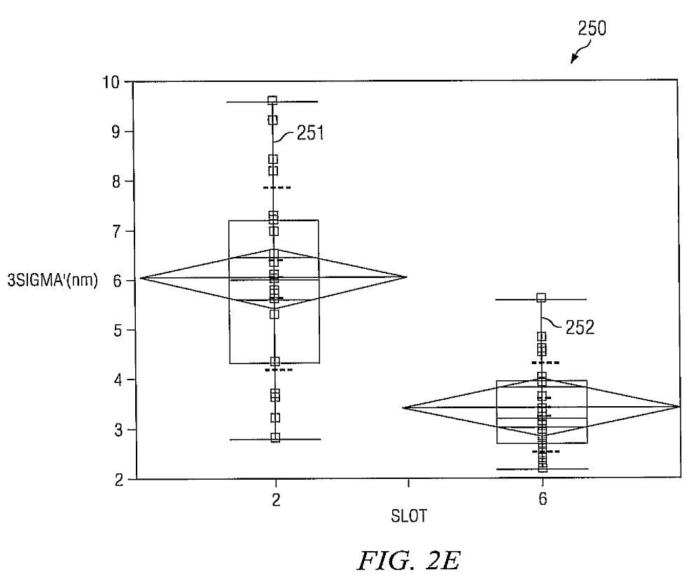

FIGS. 2A and 2C show examples of contact hole patterns prior to etching, in accordance with the principles of the present teachings.

In particular, semiconductor circuit 210 and semiconductor circuit 230 show examples of contact hole patterns before etching has removed any material. Semiconductor circuit 220 and semiconductor circuit 240 respectively show the results of etching being performed using conventional CO, SiCL₄ or CO₂-based chemistries and those produced with the SO₂-based chemistry, e.g., SO₂10₂/Ar chemistry, as disclosed herein.

FIGS. 2B and 2D show a comparison of a top-down view of a plurality of contact holes before and after etching produced with conventional CO, SiCL₄ or CO₂-based chemistries and those produced with a SO₂-based chemistry, in accordance with the principles of the present teachings.

Looking at an example individual contact hole after etching has removed layers as disclosed in FIG. 1, contact hole 222 produced with conventional CO, SiCL₄ or CO₂-based chemistries shows significant roughness along the outer perimeter. Of significance is the roughness of contact hole 222 in relation to the roughness of contact hole 224. Contact hole 222 nearly bridges to contact hole 224. If the roughness of contact hole 222 and the roughness of contact hole 224 had been even slightly greater, semiconductor circuit 220 would have been compromised by bridging of two contact holes and have possibly been useless.

In contrast, the contact hole 242 produced with the SO₂-based chemistry, e.g., SO₂/O₂/Ar chemistry, as disclosed herein shows a relatively smooth perimeter. Of significance is that the probability that contact hole 242 and contact hole 244 would bridge is nearly zero using the SO₂-based chemistry, e.g., SO₂/O₂/Ar chemistry, disclosed herein.

FIG. 2E shows a graphical analysis of the 3Sigma′ by slot for the contact holes produced with conventional CO, SiCL₄ or CO₂-based chemistries and those produced with a SO₂-based chemistry, in accordance with the principles of the present teachings.

A graphical analysis 250 of 3Sigma′ by slot shows a plot of the width of the contact holes shown on semiconductor circuit 220 from a numbered batch of semiconductors, or slot 2, as compared to the contact holes on semiconductor circuit 240 from a slot 4.

The dots along line 251 represent the various widths of the contact holes shown on semiconductor circuit 220. The dots along line 252 represent the various widths of the contact holes shown on semiconductor circuit 240. As can be seen from the measured widths of the contact holes from semiconductor circuit 220 and semiconductor circuit 240, the contact holes along line 251 produced with conventional CO, SiCL₄ or CO₂-based chemistries have nearly twice the average or mean width as the contact holes along line 252 produced with the SO₂-based chemistry, e.g., SO₂/O₂/Ar chemistry, as disclosed herein.

Not reflected in the degree of magnitude of reduction of the widths of the contact holes produced with conventional CO, SiCL₄ or CO₂-based chemistries as compared to those as produced with the SO₂/O₂/Ar chemistry as disclosed herein is the reduction of the probability of bridging to occur on a semiconductor. A nearly half reduction in the average mean width of a contact hole produced with the SO₂/O₂/Ar chemistry as disclosed herein as compared with conventional CO, SiCL₄ or CO₂-based chemistries results in a near zero probability of bridging to occur in a semiconductor produced with the SO₂/O₂/Ar chemistry.

The disclosed SO₂-based chemistry, e.g., SO₂/O₂/Ar chemistry, is used for the underlayer resist etch portion of an etching process, the dry-develop step. The SO₂-based chemistry disclosed herein provides for a uniform, thick, robust passivation layer on the sidewalls of a resist. A specific combination of pressure, flow, and power eliminates small particles of passivation material that would result in blocked etch defects, with the specific combination determined by experimentation and dependent upon the types of material being etched and the thickness thereof. Any small defects, such as spikes and burrs, are smoothed out by the passivation layer making the disclosed SO₂-based chemistry an enabling technology for a trilayer dry-develop processes.

While the teachings disclosed herein have been illustrated with respect to one or more implementations, alterations and/or modifications can be made to the illustrated examples without departing from the spirit and scope of the appended claims. In addition, while a particular feature of the disclosed teachings may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.”

Other embodiments of the teachings will be apparent to those skilled in the art from consideration of the specification and practice of the teachings disclosed herein. It is intended that the specification and examples be considered as exemplary only, with a true scope and spirit of the teachings being indicated by the following claims.

What is claimed is:

1. A method of forming a feature on a multi-layer semiconductor device, comprising:
forming a pattern feature in an uppermost layer of the multi-layer semiconductor device;
etching the multilayer semiconductor device with a SO₂ based chemistry; and
extending the pattern feature to a lower layer of the multi-layer semiconductor device.

2. The method of claim 1, wherein the SO₂ based chemistry comprises a SO₂/O₂/Ar based chemistry.

3. The method of claim 1i, wherein the SO₂ based chemistry produces a passivation film on the sidewalls of a resist as it etches.

4. The method of claim 3, further comprising the passivation film comprises sulfur and carbon compounds.

5. The method of claim 1, wherein the pattern feature is 45 nm wide.

6. The method of claim 1I, wherein the pattern feature becomes a contact hole after the etching step.

7. The method of claim 6, wherein the contact hole is a cone shape.

8. The method of claim 6, wherein a bottom of the contact hole resides in a silicide layer of the multi-layer semiconductor device.

9. The method of claim 6, wherein a top of the contact hole resides in a TEOS layer after etching.

10. The method of claim 6, wherein a top of the contact hole resides in a PR layer before the etching step.

11. A method of forming a feature on multi-layer semiconductor device, comprising:
forming a multi-layer semiconductor comprising an underlayer resist portion; and
etching the underlayer resist portion of the multi-layer semiconductor device with a SO₂-based chemistry.

12. The method of claim 11, wherein the feature is a contact hole.

13. The method of claim 11, wherein the SO₂ based chemistry comprises a SO₂/O₂/Ar based chemistry.

14. The method of claim 11, wherein the SO₂ based chemistry produces a passivation film on the sidewalls of a resist as it etches.

15. The method of claim 14, further comprising the passivation film comprises sulfur and carbon compounds.

16. The method of claim 12, wherein the contact hole is 45 nm wide.

17. The method of claim 12, wherein the contact hole is a cone shape.

18. The method of claim 12, wherein a bottom of the contact hole resides in a silicide layer of the multi-layer semiconductor device.

19. The method of claim 12, wherein a top of the contact hole resides in a TEOS layer after etching.

20. The method of claim 12, wherein a top of the contact hole resides in a PR layer before the etching step.
